(19) United States
(12) Patent Application Publication
(10) Pub. No.: US 2022/0165576 A1
(43) Pub. Date: May 26, 2022

(54) VACUUM PUMPING VALVE FOR SEMICONDUCTOR EQUIPMENT AND VACUUM CONTROL SYSTEM THEREOF

(71) Applicant: SHANGHAI HUALI INTEGRATED CIRCUIT CORPORATION, Shanghai (CN)

(72) Inventors: Yu Ren, Shanghai (CN); Zaifeng Tang, Shanghai (CN); Kaiqu Ang, Shanghai (CN); Jin Xu, Shanghai (CN)

(21) Appl. No.: 17/198,117

(22) Filed: Mar. 10, 2021

(30) Foreign Application Priority Data
Nov. 24, 2020 (CN) 202011325651.X

(51) Int. Cl. H01L 21/3065; H01J 37/305

(52) U.S. Cl. CPC H01L 21/30655; H01J 37/3053

(57) ABSTRACT

The present application discloses a vacuum pumping valve for semiconductor equipment and a vacuum control system, wherein the vacuum pumping valve includes a driving device, a base, a rotary disk, and a set of blades, wherein the blades are mounted between the base and the rotary disk, the rotary disk driven by the driving device drives the blades to move synchronously on the base, the moving blades together form a pumping orifice, the shape of the pumping orifice is a regular polygon coaxial with the rotary disk, and the opening of the pumping orifice is adjustable by means of synchronous movement of the blades. In the present application, the effective passage area of the gas flow and vacuum pressure of the reaction chamber can be controlled, and the problem of an asymmetric gas plasma distribution can be effectively resolved.

### CROSS-REFERENCES TO RELATED APPLICATIONS

This application claims the priority to Chinese patent application No. CN 202011325651.X, filed on Nov. 24, 2020, and entitled “VACUUM PUMPING VALVE FOR SEMICONDUCTOR EQUIPMENT AND VACUUM CONTROL SYSTEM THEREOF”, the disclosure of which is incorporated herein by reference in entirety.

### TECHNICAL FIELD

The present application is related to manufacturing equipment for semiconductor integrated circuits, in particular, to a vacuum pumping valve for semiconductor equipment and a vacuum control system using the vacuum pumping valve.

### BACKGROUND

In the technical field of semiconductor integrated circuits, manufacturing equipment imposes a huge impact on the yield of wafer manufacturing. With the advent of the very-large-scale integrated circuit era, the size of semiconductor wafers has gradually increased from 6 inch and 8 inch to a larger size such as 12 inch, and even 18 inch. With the wafer size increase, the requirements for semiconductor equipment in wafer manufacturing have become increasingly demanding. Taking an example of a vacuum reaction chamber, which is a reaction chamber commonly used in the wafer manufacturing process, the quality of vacuum control thereto directly affects the yield of chips on wafers.

For example, the plasma etching technology applies an etching equipment where plasma etching is performed by exciting the an etching gas. Generally, the etching gas is discharged from the gas inlet unit at the top into the reaction chamber, plasma generated by means of radio frequency excitation of the etching gas bombards the wafer held by a chuck to implement etching of the wafer.

FIG. 1 is a schematic view of a typical 8-inch wafer plasma etching machine. Referring to FIG. 1, the plasma etching machine includes a reaction chamber 100, which accommodates a chuck 110, a wafer 120 on the chuck 110, and a gas inlet unit 130 at the center of the reaction chamber 100 top. The gas inlet unit 130 is connected to a reaction gas source outside the reaction chamber to transfer the reaction gas into the reaction chamber. The reaction gas is ionized into a plasma state under the excitation of a radio frequency source and the ionized gas implements etching of the wafer. The plasma etching machine's reaction chamber is composed of a vacuum pumping valve 200 (aka gate valve) and a molecular pump 300, the molecular pump 300 pulls the reaction waste gas out of the reaction chamber 100 via the vacuum pumping valve 200 to realize vacuum in the reaction chamber 100. The requirement for plasma uniformity in the vacuum reaction chamber during the wafer process has become increasingly demanding, and the plasma also has become increasingly sensitive to the symmetry of the pumping direction of the vacuum control to the reaction chamber.

For 8-inch and 12-inch wafer technologies, to alleviate the impact of vacuum pumping on the plasma uniformity for the process equipment, equipment suppliers have to fine-adjust the equipment chamber structure individually from layout, to renew, and to reform multiple times. However, large scale produced machines cannot pre-implement such an axisymmetric individually configured vacuum pumping in the chamber, so the impact of the asymmetry in pumping direction on the advanced wafer processing has become increasingly annoying.

Referring to FIG. 1, in typical 8-inch and early 12-inch wafer plasma etching machines, the vacuum pumping valve 200 and the molecular pump 300 are placed horizontally on one side of the reaction chamber 100. In this design, the gas flow passes through two 90-degree bends (as represented by the arrows in the figure), significantly reducing the pumping speed and rendering the pumping direction eccentric. FIG. 2 is a schematic view of the etchant gas plasma flow direction in the reaction chamber of the plasma etching machine shown in FIG. 1. Referring to FIG. 2, the actual direction 510 of the plasma gas deviates from the ideal direction 520, causing an undesirable bias effect the plasma distribution in the reaction chamber, rendering asymmetric and nonuniform distribution of the plasma reaction on the wafer, so wafer yield is largely reduced. For example, non-uniform line widths across a wafer are illustrated in FIG. 3, where the bias effect in the plasma etching machine of FIG. 1 demonstrates as severe deviations from 211.32 nm to 198.51 nm.

FIG. 4 is a schematic view of a typical 12-inch wafer plasma etching machine, and FIG. 5 is a schematic view of the action of the vacuum pumping valve. FIG. 4 shows a structure in which the vacuum pumping valve 200 and the molecular pump 300 are vertically aligned below the reaction chamber 100; and FIG. 5 shows the vacuum pumping valve 200 as an integral circular structure, the arrow shows the rotation direction when some portions translate in one-way. FIGS. 8a-8c are schematic views of the vacuum pumping valve shown in FIG. 5 in different stages during an opening process, wherein the solid line curve and dashed line circle represents the rim of the vacuum pumping valve during the opening move, and the solid line or dashed line bar represents the gas flow channel. FIG. 8a illustrates a schematic view of the vacuum pumping valve in a state of being fully closed, in which case the gas flow channel is also fully closed. FIG. 8b illustrates a schematic view of the vacuum pumping valve in a state of being partially opened, in which case the gas flow channel is partially open too. FIG. 8c illustrates a schematic view of the vacuum pumping valve in a state of being opened to a limited degree, in which case the gas flow channel is in its largest open position. Relative to the wafer plasma etching machine of FIG. 1, the vacuum pumping rate is increasing with opening valve shown in FIG. 5. However, due to the asymmetry of the opened vacuum pumping valve 200, reducing the eccentricity of the gas pumping direction is not successful and the uniformity of plasma reaction on a wafer is not improved. FIG. 6 shows the gas plasma flow direction in the reaction chamber of the plasma etching machine of FIG. 4. In FIG. 6, the actual direction 510 of the gas plasma undesirably deviates from the ideal direction 520 of the gas plasma, so the bias effect is still there, causing the same problem of reaction asymmetry over the wafer thereby reducing the wafer yield. FIG. 7 shows an example of the non-uniformity effect across a wafer on line width deviations from 768.6 nm to 866.9 nm in the plasma etching machine of FIG. 4.

Therefore, in many current machines, due to the inherent design defects, the plasma eccentricity produces asymmetry when the vacuum pumping valve 200 is opened, causing increased etching rate non-uniformity on the wafer in the reaction chamber. In this case, reaction at different locations of the wafer in the reaction chamber are different, directly affecting the line width uniformity of products, deteriorating the intro-wafer uniformity performance, thereby resulting in electrical dispersion and an unstable yield.

### BRIEF SUMMARY

The present application provides a vacuum pumping valve for semiconductor equipment and a vacuum control system provided with the vacuum pumping valve, which can solve the problem of uniformity in wafer line width caused by the eccentric pumping direction during a chamber vacuum pumping process of the semiconductor equipment.

According to one embodiment of the disclosure, a vacuum pumping valve for semiconductor chip process equipment is provide, comprising: a driving device, a base, a rotary disk, and a set of blades; wherein the set of blades are mounted between the base and the rotary disk, the driving device drives the rotary disk to rotate, the rotary disk rotates the set of blades synchronously on the base, the synchronously rotating set of blades form a pumping orifice, wherein a shape of the pumping orifice is a regular polygon coaxial with the rotary disk; wherein a number of the set of blades equals to a number of sides of the pumping orifice; and wherein an opening area of the pumping orifice is adjustable by controlling a motion of the set of blades.

In some examples, the base and the rotary disk are coaxial.

In some examples, the rotary disk is a ring structure, wherein the rotary disk comprises a plurality of guide grooves evenly distributed and penetrating up and down, wherein a number of the plurality of guide grooves equals to a number of the set of blades, and wherein a center line of each of the plurality of guide grooves along an extending direction thereof does not pass through a center of the rotary disk.

In some examples, the base is a circular structure, wherein a circular gas flow channel is formed coaxial with the base, wherein a regular polygonal groove on the base is formed on a periphery of the gas flow channel, wherein a number of the sides of the regular polygonal groove equals to the number of the set of blades, and wherein both an inner side wall and an outer side wall of the regular polygonal groove are coaxial with the base.

In some examples, a guide column is formed on a top surface of each of the set of blades, and a guide block is formed at a bottom of each of the set of blades; wherein each guide column is inserted into one of the plurality of guide grooves; wherein each guide block is inserted into a groove section corresponding to one side of the regular polygonal groove; wherein two side surfaces of each of the set of blades are attached to side surfaces of adjacent ones of the set of blades; and wherein the rotary disk drives the guide block of each of set of blades to move synchronously along the groove section in which the guide block is located, by means of the guide column and the plurality of guide grooves.

In some examples, the rotary disk is a circular structure, comprising an inner ring, an outer ring, and a plurality of connecting ribs connecting the inner ring and the outer ring; wherein a number of the plurality of connecting ribs equals to the number of the set of blades, wherein the plurality of connecting ribs are evenly distributed between the inner ring and the outer ring, wherein each of the plurality of connecting ribs is provided with a guide groove penetrating up and down, and wherein the center line of the guide groove along an extending direction thereof does not pass through a center of the rotary disk.

In some examples, a top surface of the inner ring, top surfaces of the plurality of connecting ribs, and a top surface of the outer ring are on the same plane, wherein a bottom surface of the inner ring and a bottom surfaces of the plurality of connecting ribs are on a same plane, and wherein a depth of the outer ring is greater than a depth of the inner ring.

In some examples, the base is a circular structure, wherein a penetrating circular gas flow channel is formed at the center of the base, wherein a regular polygonal groove on the base is formed on a periphery of the gas flow channel, wherein a number of sides of the regular polygonal groove equals to the number of the set of blades, wherein both an inner side wall and an outer side wall of the regular polygonal groove are coaxial with the base, and wherein an outer side wall of the base is attached to the inner side wall of the outer ring of the rotary disk.

In some examples, a guide column is formed on a top surface of each of the set of blades, a guide block is formed at a bottom of each of the set of blades, wherein each guide column is inserted into one of the plurality of guide grooves, each guide block is inserted into a groove section corresponding to one side of the regular polygonal groove; wherein two side surfaces of each of the set of blades are attached to side surfaces of adjacent ones of the set of blades; and wherein the rotary disk drives the guide block of each of the set of blades to move synchronously in the groove section in which the guide block is located by means of the guide column and the guide grooves.

In some examples, a number of the set of blades is 6-12.

According to another embodiment, a vacuum control system is provided, comprising: a reaction chamber, a vacuum pumping valve, and a molecular pump, wherein the vacuum pumping valve and the molecular pump are vertically disposed directly below the reaction chamber, wherein the vacuum pumping valve is disposed between the reaction chamber and the molecular pump; wherein the vacuum pumping valve includes a driving device, a base, a rotary disk, and a set of blades, wherein the set of blades are mounted between the base and the rotary disk, wherein the driving device drives the rotary disk to rotate, the rotating rotary disk drives the set of blades to move synchronously on the base, wherein the set of blades form a pumping orifice, wherein a shape of the pumping orifice is a regular polygon coaxial with the rotary disk, wherein a number of the set of blades equals to a number of sides of the pumping orifice, and wherein the opening of the pumping orifice is adjustable by means of synchronous movement of the set of blades.

In some examples, the base and the rotary disk are coaxial.

In some examples, the rotary disk is a ring structure, comprising a plurality of guide grooves evenly distributed and penetrating up and down, wherein a number of the plurality of guide grooves equals to a number of the set of blades, and wherein a center line of each of the plurality of guide grooves in an extending direction thereof does not pass through a center of the rotary disk.

In some examples, the base is a circular structure, wherein a circular gas flow channel is formed at the center of the base, wherein a regular polygonal groove on the base is formed on a periphery of the circular gas flow channel, wherein a number of sides of the regular polygonal groove equals to the number of the set of blades, and wherein both the inner side wall and the outer side wall of the regular polygonal groove are coaxial with the base.

In some examples, a guide column is formed on a top surface of each of the set of blades, wherein a guide block is formed at a bottom of each of the set of blades, wherein a guide column is inserted into one of the plurality of guide grooves, wherein the guide block is inserted into a groove section corresponding to one side of the regular polygonal groove, wherein two side surfaces of each of the set of blades are attached to side surfaces of adjacent ones of the set of blades, and wherein the rotary disk drives the guide block of each of the set of blades to move synchronously in the groove section in which the guide block is located, by means of the guide column and the plurality of guide grooves.

In some examples, the rotary disk is a circular structure and includes an inner ring, an outer ring, and a plurality of connecting ribs connecting the inner ring and the outer ring, wherein a number of the plurality of connecting ribs equals to the number of the set of blades, wherein the connecting ribs are evenly distributed between the inner ring and the outer ring, wherein each of the plurality of connecting ribs is provided with a guide groove penetrating up and down, and wherein a center line of the guide groove in an extending direction thereof does not pass through a center of the rotary disk.

In some examples, a top surface of the inner ring, top surfaces of the plurality of connecting ribs, and a top surface of the outer ring are on a same plane, a bottom surface of the inner ring and bottom surfaces of the plurality of connecting rib are on a same plane, and wherein a depth of the outer ring is greater than a depth of the inner ring.

In some examples, the base is a circular structure, a circular gas flow channel is formed at the center of the base, a regular polygonal groove on the base is formed on a periphery of the gas flow channel, wherein a number of sides of the regular polygonal grooves equals to the number of the set of blades, wherein both an inner side wall and an outer side wall of the regular polygonal groove are coaxial with the base, the and wherein an outer side wall of the base is attached to the inner side wall of the outer ring of the rotary disk.

In some examples, a guide column is formed on a top surface of each of the set of blades, a guide block is formed at a bottom of each of the set of blades, each guide column is inserted into one of the plurality of guide grooves, the guide block is inserted into a groove section corresponding to one side of the regular polygonal groove, wherein two side surfaces of each of the set of blades are attached to side surfaces of adjacent ones of the set of blades, and wherein the rotary disk drives the guide block of each of the set of blades to move synchronously in the groove section in which the guide block is located, by means of the guide column and the plurality of guide grooves.

In some examples, a number of the set of blades is 6-12.

Compared with the current arts of a one-way translation valve, the disclosed embodiments include a structural form in which a rotary disk drives a set of blades to move synchronously on a base to form a regular polygonal pumping orifice. The valve of such a design is in a rotation opening-closing mode, and the movement of the blades is controlled by the rotation of the rotary disk, to adjust the opening size of the pumping orifice of the valve, thereby controlling the effective passage area of the gas flow and achieving the objective of controlling vacuum pressure of the reaction chamber. In addition, the vacuum pumping valve provided by the preset application can effectively solve the problem of the asymmetry plasma distribution caused by the eccentric pumping direction, implementing the flow of the gas flow in an axially symmetrical direction, and thereby improving the intro-wafer uniformity performance of the reaction chamber.

### BRIEF DESCRIPTION OF THE DRAWINGS

FIG. 1 is a schematic view of a typical 8-inch wafer plasma etching machine;

FIG. 2 is a schematic view of the gas plasma flow direction in a reaction chamber of the plasma etching machine shown in FIG. 1;

FIG. 3 is an example line width deviation on a wafer caused by the bias effect of a plasma distribution in the plasma etching machine shown in FIG. 1;

FIG. 4 is a schematic view of a typical 12-inch wafer plasma etching machine;

FIG. 5 is a view of an opening action of a vacuum pumping valve in the plasma etching machine shown in FIG. 4;

FIG. 6 is a schematic view of the gas plasma flow direction in a reaction chamber of the plasma etching machine shown in FIG. 4;

FIG. 7 is an example of line width deviation on a wafer caused by a bias effect of a plasma non-uniform distribution in the plasma etching machine shown in FIG. 4;

FIGS. 8a-8c are schematic views of the vacuum pumping valve in the plasma etching machine of FIG. 4 in fully closed, partially opened, and fully opened states;

FIG. 9a is a schematic view of a vacuum pumping valve in a fully closed state according to Embodiment 1 of the present application;

FIG. 9b is a schematic view of the vacuum pumping valve in a partially opened state according to Embodiment 1 of the present application;

FIG. 9c is a schematic view of the vacuum pumping valve at the largest open position according to Embodiment 1 of the present application;

FIG. 10 is a schematic view of a rotary disk in the vacuum pumping valve according to Embodiment 1 of the present application;

FIG. 11 is a schematic view of a base in the vacuum pumping valve according to Embodiment 1 of the present application;

FIG. 12 is a schematic two-dimensional view of a blade in the vacuum pumping valve according to Embodiment 1 of the present application;

FIG. 13 is a schematic three-dimensional view of the blade in the vacuum pumping valve according to Embodiment 1 of the present application;

FIG. 14 is a schematic view of a rotary disk in a vacuum pumping valve according to Embodiment 2 of the present application;

FIG. 15a is a schematic view of the vacuum pumping valve in a fully closed state according to Embodiment 2 of the present application;

FIG. 15b is a schematic view of the vacuum pumping valve in a partially opened state according to Embodiment 2 of the present application; and

FIG. 15c is a schematic view of the vacuum pumping valve at a largest open position according to Embodiment 2 of the present application.

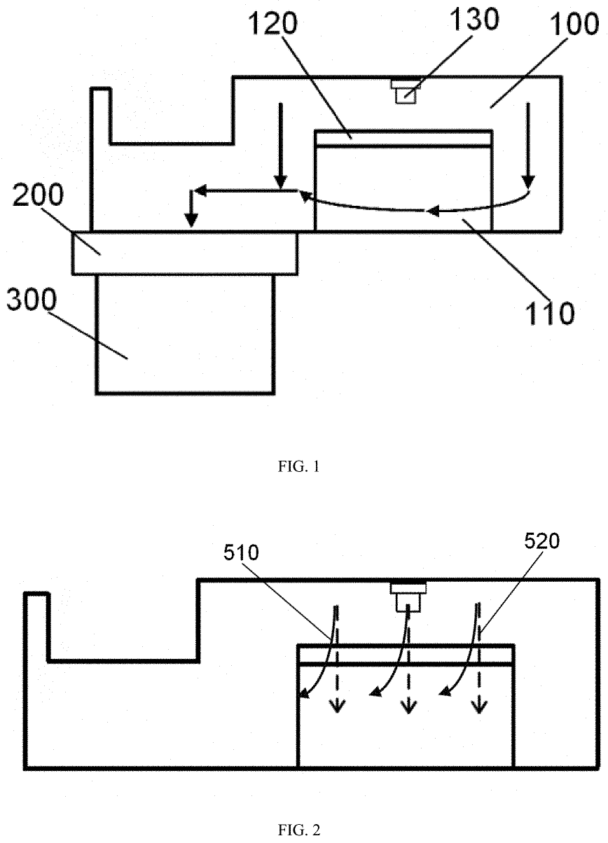

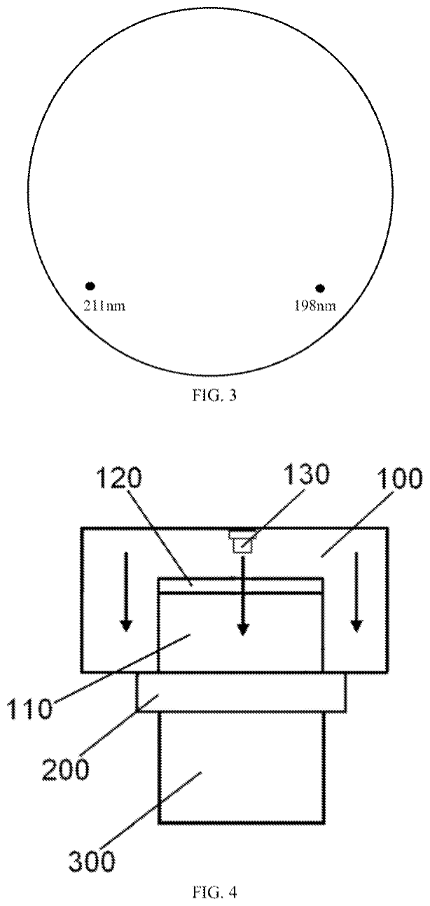

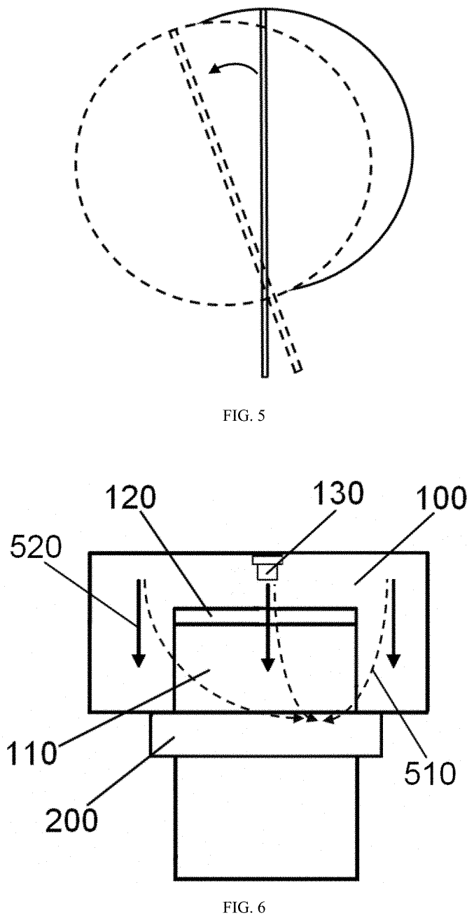

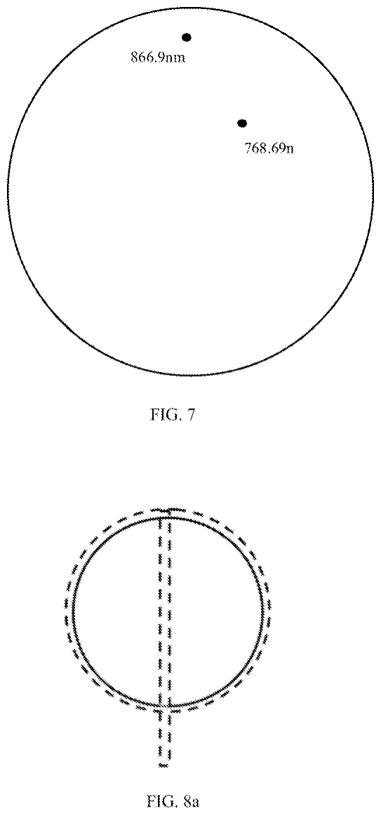

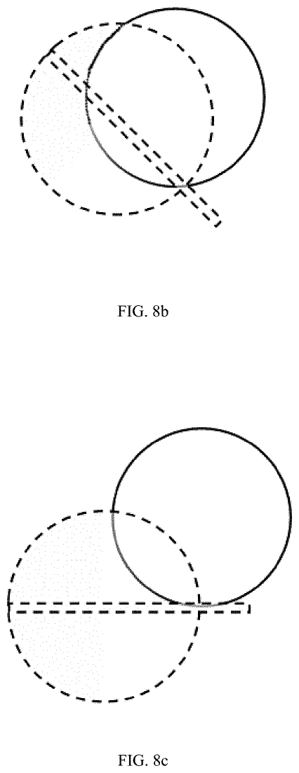

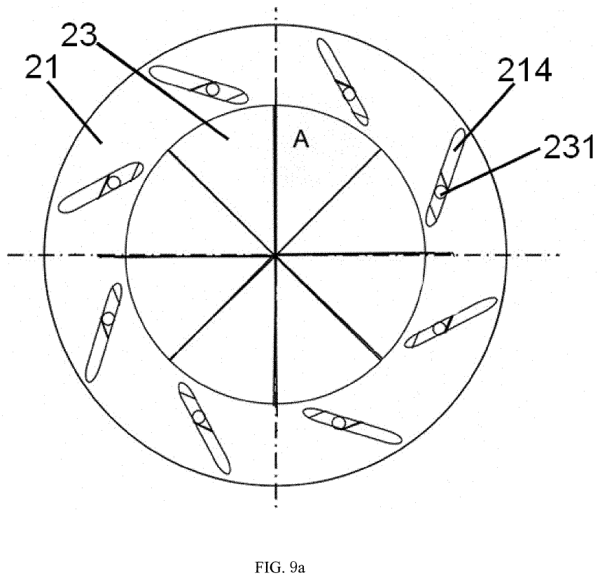

The reference numerals are explained as follows: reaction chamber 100; chuck 110; wafer 120; gas inlet unit 130; vacuum pumping valve 200; rotary disk 21; inner ring 211; outer ring 212; connecting rib 213; guide groove 214; base 22; gas flow channel 221; regular polygon groove 222; blade 23; guide column 231; guide block 232; first side surface 233; second side surface 234; first slanting surface 235; second slanting surface 236; third slanting surface 237; pumping orifice 24; and molecular pump 300.

### DETAILED DESCRIPTION OF THE APPLICATION

The implementations of the present application are described below using specific embodiments. Those skilled persons in the field could fully understand the other advantages and technical effects of the present application from the content disclosed in this specification. Obviously, the described embodiments are part of the embodiments of the present application, instead of all of them. The present application can also be implemented or applied via different specific implementations, various details in this specification can also be applied based on different viewpoints, and various modifications or changes can be made without departing from the general design concept of the present application. It should be noted that, the following embodiments and the technical features in the embodiments can be combined with each other in the case of no conflict. The following exemplary embodiments of the present application may be implemented in many different forms, and should not be construed as being limited to the specific embodiments set forth herein. It should be understood that these embodiments are provided to make the disclosure of the present application thorough and complete, and to fully convey the technical solutions of these exemplary specific embodiments to Those skilled persons in the field.

In the description of the present application, it should be noted that the orientation or position relationships indicated by the terms “center”, “close to”, “away from”, “vertical”, “perpendicular to”, “inner”, “outer”, “upper”, “lower”, “top”, “bottom”, etc. are based on the orientation or position relationships shown in the drawings, which are intended only for the convenience of describing the present application and simplifying the description, rather than indicating or implying that the apparatus or element referred to necessarily has a specific orientation or is configured or operated in a specific orientation, and thus cannot be construed as a limitation on the present application.

In the description of the present application, it should be noted that, unless otherwise clearly specified and limited, the terms “provided with”, “formed”, “mounting”, “coupling”, and “connecting” should be understood in a broad sense. For the ordinary technical persons in this field, the above terms can be understood in the context of the specific meaning of this application. In addition, the terms “first”, “second”, and “third” are used in the following embodiments for describing different elements and components, which, however, should not be limited by these terms, since these terms are used only for distinguishing between these elements and components. Therefore, without departing from the teaching of the embodiments of the present application, the first element or component discussed below may also be referred to as the second element or component.

The vacuum pumping valve 200 for semiconductor equipment provided by the present application includes a driving device, a base 22, a rotary disk 21, and a set of blades 23, wherein the blades 23 are mounted between the base 22 and the rotary disk 21. The driving device drives the rotary disk 21 to rotate, the rotating rotary disk 21 drives the blades 23 to move synchronously on the base 22, the synchronously moving blades 23 together form a pumping orifice 24, the shape of the pumping orifice 24 is a regular polygon centering at the center of the rotary disk 21. The number of the blades 23 is the same as the number of sides of the pumping orifice 24 polygon, and the opening size of the pumping orifice 24 is adjusted while keeping synchronous movements of the blades 23.

In an embodiment of the present application, the vacuum pumping valve 200 is applied to a vacuum control system of the plasma etching machine. The vacuum control system includes a reaction chamber 100, a vacuum pumping valve 200, and a molecular pump 300. The vacuum pumping valve 200 is disposed vertically directly below the symmetrical reaction chamber 100, and the molecular pump 300 is disposed vertically directly below the vacuum pumping valve 200. The molecular pump 300 vacuumizes the reaction chamber 100 by means of the vacuum pumping valve 200. The reaction chamber 100 includes a chuck 110, a wafer 120 held on the chuck 110, and a gas inlet unit 130 at the top of the reaction chamber 100. The gas inlet unit 130 is connected to a gas source outside the reaction chamber 100.

Taking the plasma etching machine as an example, in the vacuum pumping valve, the driving device drives the rotary disk 21 to rotate, and then the rotary disk 21 drives a set of blades 23 to move synchronously on the base 22 to form a regular polygonal pumping orifice 24. In such a structure, the opening-closing state of the valve changes from an full-valve one-way translation movement in the existing machine to this disclosed synchronous opening-closing movement in the radial direction. The synchronous movement of the blades 23 is controlled by the rotating rotary disk 21, to adjust the size of the pumping orificeorifice of the valve, thereby accurately controlling the effective passage area of the gas flow and achieving the objective of controlling vacuum pressure of the reaction chamber. In this way, the vacuum pumping valve can significantly improve the defect of the eccentric pumping direction, and can effectively solve the problem of asymmetry and nonuniformity of the plasma distribution caused by the eccentric pumping direction, implementing flow of the gas flow in an axisymmetric direction, improving the uniformity and symmetry of etching in the reaction chamber, and thereby achieving the objective of improving the intro-wafer uniformity performance of the reaction chamber. Necessarily, the above vacuum pumping valve can also be applied to a vacuum control system of other asymmetric vacuum chamber to optimize the pumping uniformity.

Specifically, the center of the base 22 and the center of the rotary disk 21 are on the same vertical line.

In an example Embodiment 1 of the present application, the rotary disk 21 is a ring structure as shown in FIG. 10, on which a plurality of guide grooves 214 penetrating up and down are evenly distributed. The number of the guide grooves 214 is the same as the number of the blades 23, and the center line of the guide groove 214 in the extending direction thereof does not pass through the center of the rotary disk 21.

Referring to FIG. 11, the base 22 is a circular structure, a penetrating circular gas flow channel 221 is formed at the center of the base 22, and a regular polygonal groove is formed on the periphery of the gas flow channel 221 on the base 22. The number of the sides of the regular polygonal groove is the same as the number of the blades 23, and both the inner side wall of the regular polygonal groove being close to the center of the base 22 and the outer side of the regular polygonal groove being wall away from the center of the base 22 are centered on the center of the base 22.

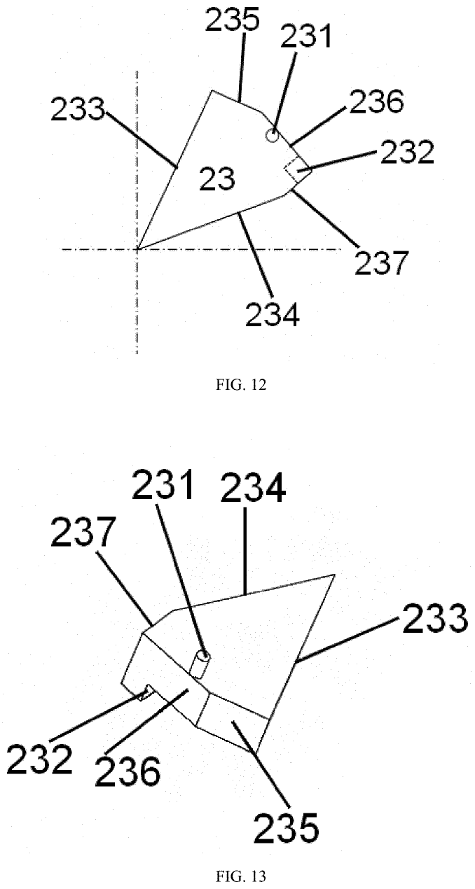

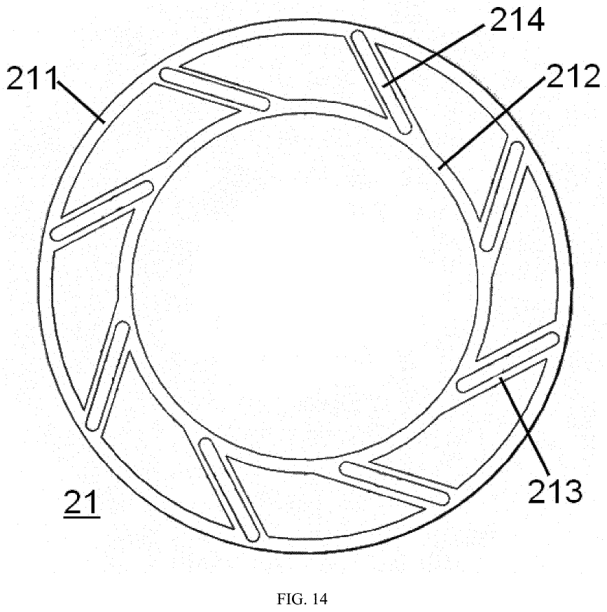

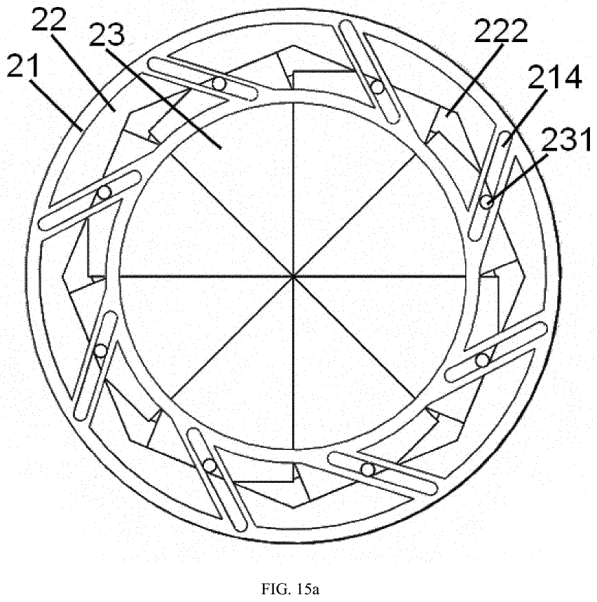

Referring to FIGS. 12 and 13, a guide column 231 is formed on the top surface of each blade 23, and a guide block 232 is formed at the bottom of each blade 23. Each guide column 231 is inserted into one of the guide grooves 214, and each guide block 232 is inserted into a groove section corresponding to one side of the regular polygonal groove. Two side surfaces of each blade 23 each are attached to a side surface of an adjacent blade, and the rotating rotary disk 21 drives, by means of the guide columns 231 and the guide grooves 214, the guide blocks 232 of all the blades 23 to move synchronously in the groove sections in which the guide blocks are located.

An example of 8 blades is used to describe the component composition and structure of the vacuum pumping valve 200 in Embodiment 1 of the present application in detail.

Referring to FIG. 10, eight guide grooves 214 penetrating up and down are evenly distributed on the rotary disk 21, and each guide groove 214 is provided for the guide column 231 on the blade 23 to be mounted therein. In an embodiment of the present application, the driving device is configured to be a device capable of driving the rotary disk 21 to rotate and including, for example, a motor and a belt transmission structure. A driving wheel is mounted on the output shaft of the motor, a belt is sleeved on the driving wheel and the outer circumferential surface of the rotary disk 21. The motor drives the driving wheel to rotate, and the driving wheel drives the rotary disk 21 to rotate by means of the belt. Necessarily, in other embodiments, those skilled persons in the field could also employ a driving device in other structural form.

Referring to FIG. 11, a circular gas flow channel 221 is formed at the center of the base 22 of the circular structure, and the center of the gas flow channel 221 coincides with the center of the base 22. A regular octagonal groove 222 on the base 22 is formed on the periphery of the gas flow channel 221, the regular octagonal groove 222 is formed by connecting eight identical groove sections, and each groove section is provided for the guide block 232 on the blade 23 to be inserted thereto. In the regular octagonal groove, the outer side wall of the regular octagon and the inner side wall of the regular octagon both are centered on the center of the gas flow channel 221. The outer side wall and the inner side wall each are composed of eight vertical surfaces, and each vertical surface of the outer side wall is parallel to a corresponding vertical surface of the inner side wall located on the inner side thereof.

Referring to FIGS. 12 and 13, the blade 23 has a first side surface 233, a second side surface 234, a first slanting surface 235, a second slanting surface 236, and a third slanting surface 237. The guide column 231 is formed on the top surface of the blade 23 and located at the second slanting surface 236, and the guide block 232 is formed at the bottom of the blade 23 and located at a junction between the second slanting surface 236 and the third slanting surface 237.

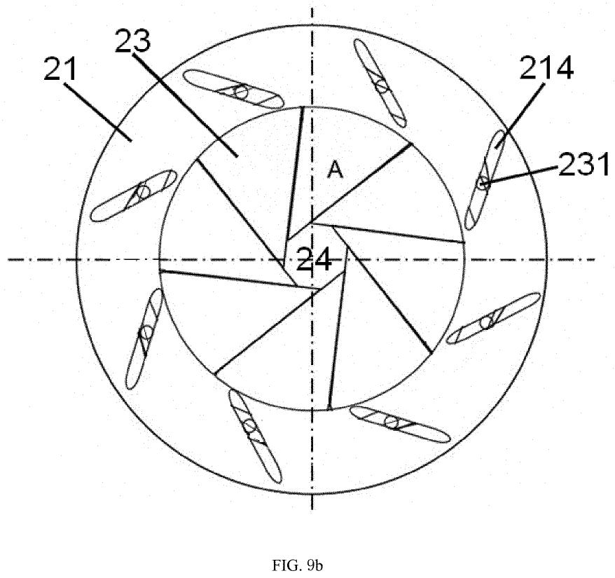

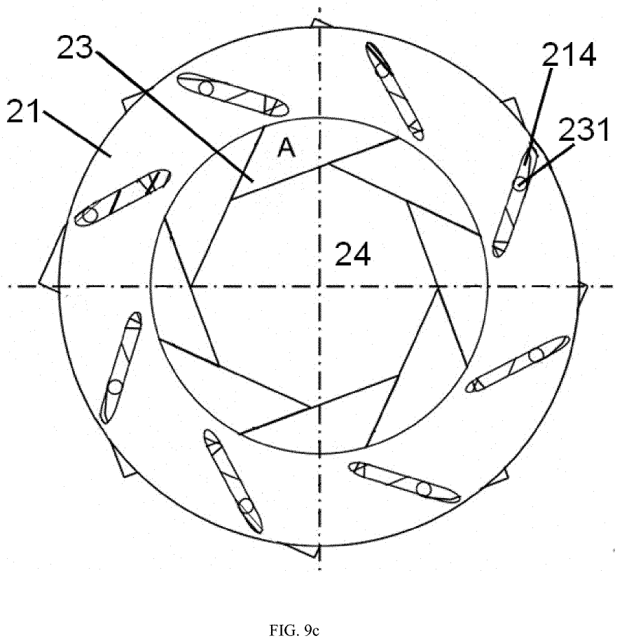

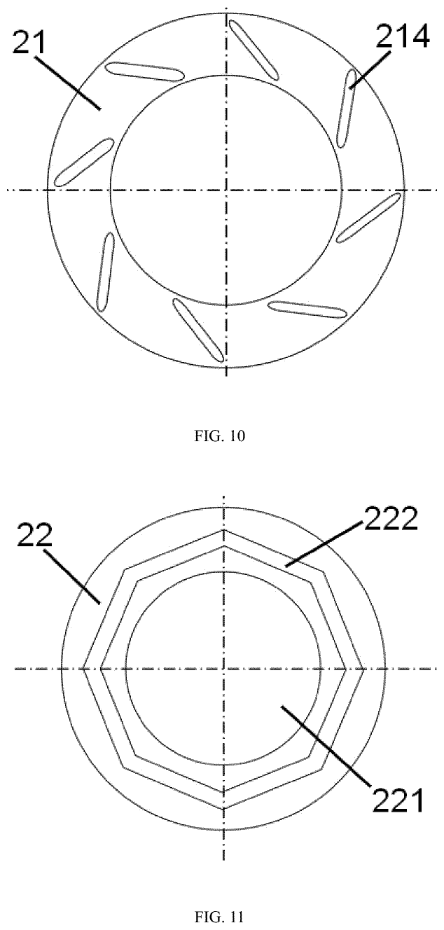

FIG. 9a is a schematic view of the vacuum pumping valve in a fully closed state according to Embodiment 1 of the present application. Referring to FIG. 9a, the guide column 231 of each blade 23 is inserted into the guide groove 214 of the rotary disk 21, and the guide block 232 of each blade 23 is inserted into a groove section of the regular octagonal groove 222 of the base 22. In this case, the first side surface 233 of each blade 23 is attached to the second side surface 234 of an adjacent blade 23 on one side thereof, and the second side surface 234 of the blade 23 is attached to the first side surface 233 of an adjacent blade on the other side thereof, in which case the gas flow channel 221 is fully closed.

FIG. 9b is a schematic view of the vacuum pumping valve in a partially opened state according to Embodiment 1 of the present application. Referring to FIG. 9b, the rotary disk 21 driven by the driving device (not shown in the figure) rotates counterclockwise, the rotary disk 21 drives the blades 23 to move synchronously, by means of the guide grooves 214 and the guide columns 231, and the guide block 232 in the blade 23 slides in the groove section in which the guide block is located. The synchronous movement of the blades 23 forms the regular octagonal pumping orifice 24, so that the gas flow channel 221 is opened.

FIG. 9c is a schematic view of the vacuum pumping valve at its largest opening orifice according to Embodiment 1 of the present application. Referring to FIG. 9c, driven by the rotary disk 21, each blade 23 moves to a limiting position relative to the base 22, in which case the pumping orifice 24 reaches a maximum size.

In an example Embodiment 2 of the present application, the rotary disk 21 is a circular structure as shown in FIG. 14 and includes an inner ring 211, an outer ring 212, and a plurality of connecting ribs 213 connecting the inner ring 211 and the outer ring 212. The center of the inner ring 211 coincides with the center of the outer ring 212, and the number of the connecting ribs 213 is the same as the number of the blades 23. The connecting ribs 213 are evenly distributed between the inner ring 211 and the outer ring 212, and each of the connecting ribs 213 is provided with a guide groove 214 penetrating the disk between the inner ring and outer ring up and down. The center line of the guide groove 214 in the extending direction thereof does not pass through the center of the rotary disk 21 (i.e., the center of the inner ring 211 and the center of the outer ring 212).

The top surface of the inner ring 211, the top surface of the connecting rib 213, and the top surface of the outer ring 212 are on the same plane, the bottom surface of the inner ring 211 and the bottom surface of the connecting rib 213 are on the same plane, and the depth of the outer ring 212 is greater than the height of the inner ring 211. In some examples, the depth difference between the outer ring 212 and the inner ring 211 is greater than or equal to the thickness of the blade 23.

Referring to FIG. 11, the base 22 is a circular structure, the cross section of the circular gas flow channel 221 is centered in the disk area of the base 22. A regular polygonal groove on the base 22 is formed on the periphery of the gas flow channel 221, the number of sides of the regular polygonal groove is the same as the number of the blades 23. Both the inner side wall and the outer side wall of the regular polygonal groove are coaxial with the base 22. The outer side wall of the base 22 is attached to the inner side wall of the outer ring 212 of the rotary disk 21.

Specifically, a guide column 231 is formed on the top surface of each blade 23, and a guide block 232 is formed at the bottom of each blade 23. Each guide column 231 is inserted into one of the guide grooves 214, and each guide block 232 is inserted into a groove section corresponding to one side of the regular polygonal groove. Two side surfaces of each blade 23 each are attached to a side surface of an adjacent blade, and the rotating rotary disk 21 drives, by means of the guide columns 231 and the guide grooves 214, the guide blocks 232 of all the blades 23 to move synchronously in groove sections in which the guide blocks are located.

The number of blades in the vacuum pumping valve is configure based on specific needs. Although more blades helps with pumping axisymmetrically in the gas distribution, increase in the number of the blades may increase the risk of generation of particles by the equipment. Therefore, in consideration between the axisymmetric requirement for pumping and avoidance of particle generation by the equipment, specifically, the number of the blades is chosen to be from 6 to 12 according to the embodiments of the present application.

An example of 8 blades is used to describe the component composition and structure of the vacuum pumping valve 200 in detail.

Referring to FIG. 14, the inner ring 211 and the outer ring 212 of the rotary disk 21 are connected by eight connecting ribs 213, and the guide groove 214 is formed on each connecting rib 213 for the guide column 231 on the blade 23 to be mounted therein. In an embodiment of the present application, the driving device is configured to be a device capable of driving the rotary disk 21 to rotate and including, for example, a motor and a belt transmission structure. A driving wheel is mounted on the output shaft of the motor, and a belt is sleeved on the driving wheel and the outer ring 212 of the rotary disk 21. The motor drives the driving wheel to rotate, and the driving wheel drives the rotary disk 21 to rotate by means of the belt. Necessarily, in other embodiments, those skilled persons in the field could also employ a driving device in other structural form.

Referring to FIG. 11, a circular gas flow channel 221 is formed coaxial with the circular base 22. A regular octagonal groove 222 on the base 22 is formed on the periphery of the gas flow channel 221, the regular octagonal groove 222 is formed by connecting eight identical groove sections, and each groove section is provided for the guide block 232 on the blade 23 to be inserted thereto. In the regular octagonal groove, the outer side wall of the regular octagon and the inner side wall of the regular octagon both are centered on the center of the gas flow channel 221. The outer side wall and the inner side wall each are composed of eight vertical surfaces, and each vertical surface of the outer side wall is parallel to a corresponding vertical surface of the inner side wall located on the inner side thereof.

Referring to FIGS. 12 and 13, the blade 23 has a first side surface 233, a second side surface 234, a first slanting surface 235, a second slanting surface 236, and a third slanting surface 237. The guide column 231 is formed on the top surface of the blade 23 and located at the second slanting surface 236, and the guide block 232 is formed at the bottom of the blade 23 and located at a junction between the second slanting surface 236 and the third slanting surface 237.

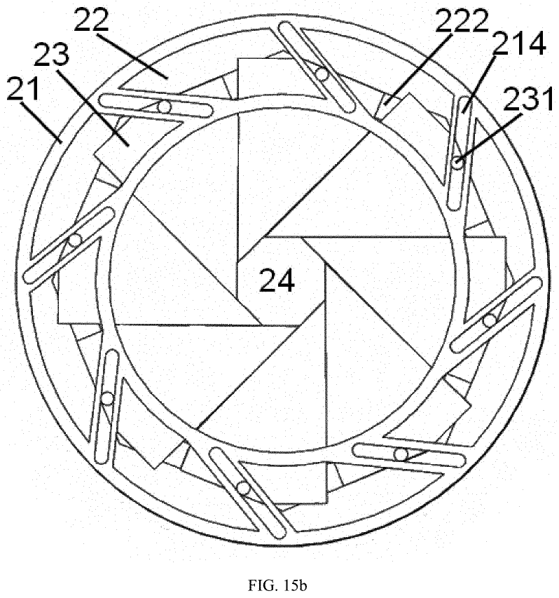

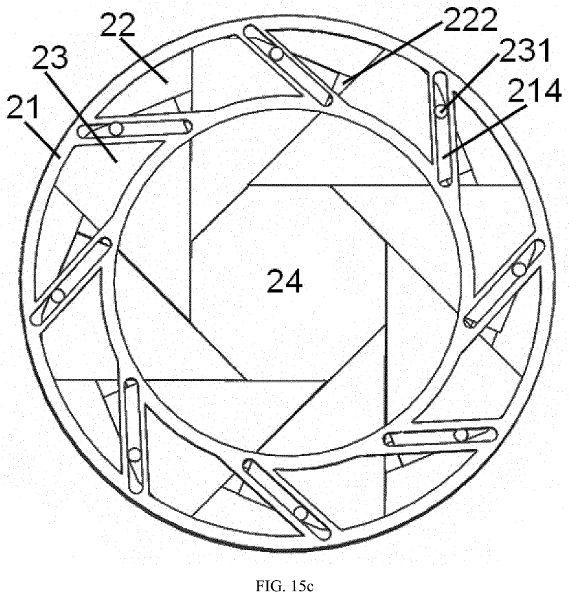

FIG. 15a is a schematic view of the vacuum pumping valve in a fully closed state according to this embodiment of the present application. Referring to FIG. 15a, the guide column 231 of each blade 23 is inserted into the guide groove 214 on the connecting rib 213 of the rotary disk 21, and the guide block 232 of each blade 23 is inserted into a groove section of the regular octagonal groove 222 of the base 22. In this case, the first side surface 233 of each blade 23 is attached to the second side surface 234 of an adjacent blade 23 on one side thereof, and the second side surface 234 of the blade 23 is attached to the first side surface 233 of an adjacent blade on the other side thereof, in which case the gas flow channel 221 is fully closed.

FIG. 15b is a schematic view of the vacuum pumping valve in a partially opened state according to this embodiment of the present application. Referring to FIG. 15b, the rotary disk 21 driven by the driving device (not shown in the figure) rotates counterclockwise, the rotary disk 21 drives, by means of the guide grooves 214 and the guide columns 231, the blades 23 to move synchronously, and the guide block 232 in the blade 23 slides in the groove section in which the guide block is located. The synchronous movement of the blades 23 forms the regular octagonal pumping orifice 24, so that the gas flow channel 221 is opened.

FIG. 15c is a schematic view of the vacuum pumping valve at its maximum opening orifice according to this embodiment of the present application. Referring to FIG. 15c, the first slanting surface 235 of the blade 23 is attached to the inner side wall of the outer ring 212 of the rotary disk 21, in which case the blade 23 moves to a limiting position and the pumping orifice 24 reaches a maximum opening.

It can be seen from the above-described action process that, in the vacuum pumping valve, the rotary disk drives all the blades to perform a synchronous opening-closing movement in the radial direction thereof, to uniformly adjust the size (i.e., open degree) of the pumping orifice of the valve, thereby accurately controlling the effective passage area of the gas flow and vacuum pressure of the reaction chamber. In this way, the defect of the eccentric pumping direction can be significantly improved, implementing flow of the gas flow in an axisymmetric direction, and thereby improving the uniformity and symmetry of etching in the reaction chamber.

In an embodiment of the present application, a vacuum control system is further provided, including a reaction chamber 100, a vacuum pumping valve 200, and a molecular pump 300. The vacuum pumping valve 200 and the molecular pump 300 are vertically disposed directly below the reaction chamber 100, and the vacuum pumping valve 200 is disposed between the reaction chamber 100 and the molecular pump 300.

The vacuum pumping valve 200 includes a driving device, a base 22, a rotary disk 21, and a set of blades 23, wherein the blades 23 are mounted between the base 22 and the rotary disk 21, the driving device drives the rotary disk 21 to rotate, the rotating rotary disk 21 drives the blades 23 to move synchronously on the base 22, the synchronously moving blades 23 together form a pumping orifice 24, the shape of the pumping orifice 24 is a regular polygon centering on the center of the rotary disk 21, the number of the blades 23 is the same as the number of sides of the pumping orifice 24, and the open degree of the pumping orifice 24 is adjusted by means of synchronous movement of the blades 23.

To sum up, in the vacuum control system provided by the present application, a one-way translation valve is improved into a structural form in which a rotary disk drives a set of blades to move synchronously on a base to form a regular polygonal pumping orifice. The valve of such a design is in a rotation opening-closing mode, and the movement of the blades is controlled by the rotation of the rotary disk, to adjust the size of the pumping orifice of the valve, thereby controlling the effective passage area of the gas flow and achieving the objective of controlling vacuum pressure of the reaction chamber. In addition, the vacuum pumping valve provided by the preset application can effectively solve the problem of the asymmetry plasma distribution caused by the eccentric pumping flow, implementing the flow of the gas flow in an axially symmetrical direction, and thereby improving the intro-wafer uniformity performance of the reaction chamber.

The present application is described above in detail using specific embodiments. The above-described embodiments are merely some examples of the present application, and the present application is not limited to the above-mentioned implementations. Equivalent replacements and improvements made by those skilled persons in the field without departing from the principle of the present application should be regarded as falling within the technical scope protected by the present application.

What is claimed is:

1. A vacuum pumping valve for semiconductor chip process equipment, comprising:
a driving device, a base, a rotary disk, and a set of blades;
wherein the set of blades are mounted between the base and the rotary disk, the driving device drives the rotary disk to rotate, the rotary disk rotates the set of blades synchronously on the base, the synchronously rotating set of blades form a pumping orifice, wherein a shape of the pumping orifice is a regular polygon coaxial with the rotary disk; wherein a number of the set of blades equals to a number of sides of the pumping orifice; and wherein an opening area of the pumping orifice is adjustable by controlling a motion of the set of blades.

2. The vacuum pumping valve for semiconductor equipment according to claim 1, wherein the base and the rotary disk are coaxial.

3. The vacuum pumping valve for semiconductor equipment according to claim 2, wherein the rotary disk is a ring structure, wherein the rotary disk comprises a plurality of guide grooves evenly distributed and penetrating up and down, wherein a number of the plurality of guide grooves equals to a number of the set of blades, and wherein a center line of each of the plurality of guide grooves along an extending direction thereof does not pass through a center of the rotary disk.

4. The vacuum pumping valve for semiconductor equipment according to claim 3, wherein the base is a circular structure, wherein a circular gas flow channel is formed coaxial with the base, wherein a regular polygonal groove on the base is formed on a periphery of the gas flow channel, wherein a number of the sides of the regular polygonal groove equals to the number of the set of blades, and wherein both an inner side wall and an outer side wall of the regular polygonal groove are coaxial with the base.

5. The vacuum pumping valve for semiconductor equipment according to claim 4, wherein a guide column is formed on a top surface of each of the set of blades, and a guide block is formed at a bottom of each of the set of blades; wherein each guide column is inserted into one of the plurality of guide grooves; wherein each guide block is inserted into a groove section corresponding to one side of the regular polygonal groove; wherein two side surfaces of each of the set of blades are attached to side surfaces of adjacent ones of the set of blades; and wherein the rotary disk drives the guide block of each of set of blades to move synchronously along the groove section in which the guide block is located, by means of the guide column and the plurality of guide grooves.

6. The vacuum pumping valve for semiconductor equipment according to claim 2, wherein the rotary disk is a circular structure, comprising an inner ring, an outer ring, and a plurality of connecting ribs connecting the inner ring and the outer ring; wherein a number of the plurality of connecting ribs equals to the number of the set of blades, wherein the plurality of connecting ribs are evenly distributed between the inner ring and the outer ring, wherein each of the plurality of connecting ribs is provided with a guide groove penetrating up and down, and wherein the center line of the guide groove along an extending direction thereof does not pass through a center of the rotary disk.

7. The vacuum pumping valve for semiconductor equipment according to claim 6, wherein a top surface of the inner ring, top surfaces of the plurality of connecting ribs, and a top surface of the outer ring are on the same plane, wherein a bottom surface of the inner ring and a bottom surfaces of the plurality of connecting ribs are on a same plane, and wherein a depth of the outer ring is greater than a depth of the inner ring.

8. The vacuum pumping valve for semiconductor equipment according to claim 6, wherein the base is a circular structure, wherein a penetrating circular gas flow channel is formed at the center of the base, wherein a regular polygonal groove on the base is formed on a periphery of the gas flow channel, wherein a number of sides of the regular polygonal groove equals to the number of the set of blades, wherein both an inner side wall and an outer side wall of the regular polygonal groove are coaxial with the base, and wherein an outer side wall of the base is attached to the inner side wall of the outer ring of the rotary disk.

9. The vacuum pumping valve for semiconductor equipment according to claim 8, wherein a guide column is formed on a top surface of each of the set of blades, a guide block is formed at a bottom of each of the set of blades, wherein each guide column is inserted into one of the plurality of guide grooves, each guide block is inserted into a groove section corresponding to one side of the regular polygonal groove; wherein two side surfaces of each of the set of blades are attached to side surfaces of adjacent ones of the set of blades; and wherein the rotary disk drives the guide block of each of the set of blades to move synchronously in the groove section in which the guide block is located by means of the guide column and the guide grooves.

10. The vacuum pumping valve for semiconductor equipment according to claim 1, wherein a number of the set of blades is in a range of 6-12.

11. A vacuum control system, comprising: a reaction chamber, a vacuum pumping valve, and a molecular pump, wherein the vacuum pumping valve and the molecular pump are vertically disposed directly below the reaction chamber, wherein the vacuum pumping valve is disposed between the reaction chamber and the molecular pump; wherein the vacuum pumping valve includes a driving device, a base, a rotary disk, and a set of blades, wherein the set of blades are mounted between the base and the rotary disk, wherein the driving device drives the rotary disk to rotate, the rotating rotary disk drives the set of blades to move synchronously on the base, wherein the set of blades form a pumping orifice, wherein a shape of the pumping orifice is a regular polygon coaxial with the rotary disk, wherein a number of the set of blades equals to a number of sides of the pumping orifice, and wherein the opening of the pumping orifice is adjustable by means of synchronous movement of the set of blades.

12. The vacuum control system according to claim 11, wherein the base and the rotary disk are coaxial.

13. The vacuum control system according to claim 12, wherein the rotary disk is a ring structure, comprising a plurality of guide grooves evenly distributed and penetrating up and down, wherein a number of the plurality of guide grooves equals to a number of the set of blades, and wherein a center line of each of the plurality of guide grooves in an extending direction thereof does not pass through a center of the rotary disk.

14. The vacuum control system according to claim 13, wherein the base is a circular structure, wherein a circular gas flow channel is formed at the center of the base, wherein a regular polygonal groove on the base is formed on a periphery of the circular gas flow channel, wherein a number of sides of the regular polygonal groove equals to the number of the set of blades, and wherein both the inner side wall and the outer side wall of the regular polygonal groove are coaxial with the base.

15. The vacuum control system according to claim 14, wherein a guide column is formed on a top surface of each of the set of blades, wherein a guide block is formed at a bottom of each of the set of blades, wherein a guide column is inserted into one of the plurality of guide grooves, wherein the guide block is inserted into a groove section corresponding to one side of the regular polygonal groove, wherein two side surfaces of each of the set of blades are attached to side surfaces of adjacent ones of the set of blades, and wherein the rotary disk drives the guide block of each of the set of blades to move synchronously in the groove section in which the guide block is located, by means of the guide column and the plurality of guide grooves.

16. The vacuum control system according to claim 12, wherein the rotary disk is a circular structure and includes an inner ring, an outer ring, and a plurality of connecting ribs connecting the inner ring and the outer ring, wherein a number of the plurality of connecting ribs equals to the number of the set of blades, wherein the connecting ribs are evenly distributed between the inner ring and the outer ring, wherein each of the plurality of connecting ribs is provided with a guide groove penetrating up and down, and wherein a center line of the guide groove in an extending direction thereof does not pass through a center of the rotary disk.

17. The vacuum control system according to claim 16, wherein a top surface of the inner ring, top surfaces of the plurality of connecting ribs, and a top surface of the outer ring are on a same plane, a bottom surface of the inner ring and bottom surfaces of the plurality of connecting rib are on a same plane, and wherein a depth of the outer ring is greater than a depth of the inner ring.

18. The vacuum control system according to claim 16, wherein the base is a circular structure, a circular gas flow channel is formed at the center of the base, a regular polygonal groove on the base is formed on a periphery of the gas flow channel, wherein a number of sides of the regular polygonal grooves equals to the number of the set of blades, wherein both an inner side wall and an outer side wall of the regular polygonal groove are coaxial with the base, the and wherein an outer side wall of the base is attached to the inner side wall of the outer ring of the rotary disk.

19. The vacuum control system according to claim 18, wherein a guide column is formed on a top surface of each of the set of blades, a guide block is formed at a bottom of each of the set of blades, each guide column is inserted into one of the plurality of guide grooves, the guide block is inserted into a groove section corresponding to one side of the regular polygonal groove, wherein two side surfaces of each of the set of blades are attached to side surfaces of adjacent ones of the set of blades, and wherein the rotary disk drives the guide block of each of the set of blades to move synchronously in the groove section in which the guide block is located, by means of the guide column and the plurality of guide grooves.

20. The vacuum control system according to claim 11, wherein a number of the set of blades is in a range of 6-12.
